(19) United States
(12) Patent Application Publication
(10) Pub. No.: US 2007/0176295 A1
(43) Pub. Date: Aug. 2, 2007

(54) CONTACT VIA SCHEME WITH STAGGERED VIAS

(75) Inventors: Anil K. Chinthakindi, Wappingers Falls, NY (US); Douglas D. Coolbaugh, Essex Junction, VT (US); Jason P. Gill, Essex Junction, VT (US); Douglas W. Kemerer, Essex Junction, VT (US); Tom C. Lee, Essex Junction, VT (US)

Correspondence Address: HOFFMAN, WARNICK & D'ALESSANDRO LLC, 75 STATE ST, 14TH FL, ALBANY, NY, 12207, US

(73) Assignee: INTERNATIONAL BUSINESS MACHINES CORPORATION, Armonk, NY (US)

(21) Appl. No.: 11/307,325

(22) Filed: Feb. 1, 2006

(51) Int. Cl. H01L 21/44

(52) U.S. Cl. 257/774; 438/666

(57) ABSTRACT

A contact via scheme with staggered contact vias to, interalia, increase current density of a resistor by mitigating electromigration and reducing the resistive heating of each contact via is disclosed. The contact via scheme increases the current density of a thin film resistor by increasing the number of current carrying contact vias and by arranging the contact vias in staggered arrangement, which redistributes the current at the ends of the resistor. Hence, the contact via scheme decreases the current density per contact via and enables a higher maximum current density for the resistor. A method and a semiconductor device are also disclosed.

### BACKGROUND OF THE INVENTION

1. Technical Field

The invention relates generally to contact via schemes, and more particularly, to a contact via scheme with staggered contact vias to increase a current density of a resistor by mitigating electromigration and reducing the resistive heating of each contact via.

2. Background Art

With continued miniaturization of circuitry in the semiconductor industry, integration of passive components on chips is becoming more and more complex. For example, most of the input/output (I/O) circuits used in application specific integrated circuits (ASICs) require a precision resistor for low power applications. Current back end of line (BEOL) based thin film resistors are made of, for example, tantalum nitride (TaN). These materials are preferred over polysilicon because the resistors made of these materials provide excellent tolerances and lower parasitic capacitance to the substrate.

FIGS. 1 and 2 illustrate a prior art contact via scheme 10 for connecting a metal layer 12 and a back end of line (BEOL) thin film resistor 14 with a barrier layer 15 thereover. FIG. 1 shows thin film resistor 14 partially revealed. Contact via scheme 10 includes a plurality of aligned contact vias 16 connecting metal layer 12 and thin film resistor 14.

One challenge relative to the more complex I/O circuits and thin film resistor 14 is providing resistor 14 with higher current carrying capability. The above-described technologies offer resistors with a current density maximum of approximately 0.5 milli-Ampere per micrometer (mA/μm) width of resistor. Unfortunately, current densities of approximately 1 mA/μm width of resistor are desired for future applications in 65 nanometer (nm) technologies and beyond.

In view of the foregoing, there is a need in the art for a solution that does not suffer from the problems of the related art.

### SUMMARY OF THE INVENTION

A contact via scheme with staggered contact vias to, interalia, increase a current density of a resistor by mitigating electromigration and reducing the resistive heating of each contact via is disclosed. The contact via scheme increases the current density of a thin film resistor by increasing the number of current carrying contact vias and by arranging the contact vias in a staggered arrangement, which redistributes the current at the ends of the resistor. Hence, the contact via scheme decreases the current density per contact via and enables a higher maximum current density for the resistor. A method and a semiconductor device are also disclosed.

A first aspect of the invention provides a contact via scheme comprising: a plurality of contact vias connecting a metal layer to a resistor, wherein the plurality of contact vias are positioned in a staggered arrangement.

A second aspect of the invention provides a method of connecting a metal layer and a resistor on a semiconductor chip, the method comprising the step of: forming a plurality of contact vias connecting the metal layer to the resistor, wherein the plurality of contact vias are positioned in a staggered arrangement.

A third aspect of the invention provides a semiconductor device comprising: a metal layer; a resistor; a first row of contact vias connecting the metal layer to the thin film resistor; and at least one second row of contact vias connecting the metal layer to the resistor, wherein each row of contact vias is offset relative to an adjacent row of contact vias.

The illustrative aspects of the present invention are designed to solve the problems herein described and/or other problems not discussed.

### BRIEF DESCRIPTION OF THE DRAWINGS

These and other features of this invention will be more readily understood from the following detailed description of the various aspects of the invention taken in conjunction with the accompanying drawings that depict various embodiments of the invention, in which:

FIG. 1 shows a plan view of a prior art contact via scheme for connecting a metal layer and a resistor.

FIG. 2 shows a cross-sectional view of the prior art contact via scheme of FIG. 1.

FIG. 3 shows a cross-sectional view of one embodiment of a contact via scheme according to the invention.

FIG. 4 shows a plan view of one embodiment of the contact via scheme of FIG. 3.

FIGS. 5 and 6 show steps of one embodiment of a method of connecting a metal layer and a resistor on a semiconductor chip according to the invention.

It is noted that the drawings of the invention are not to scale. The drawings are intended to depict only typical aspects of the invention, and therefore should not be considered as limiting the scope of the invention. In the drawings, like numbering represents like elements between the drawings. However, like shading does not necessarily indicate like materials.

### DETAILED DESCRIPTION

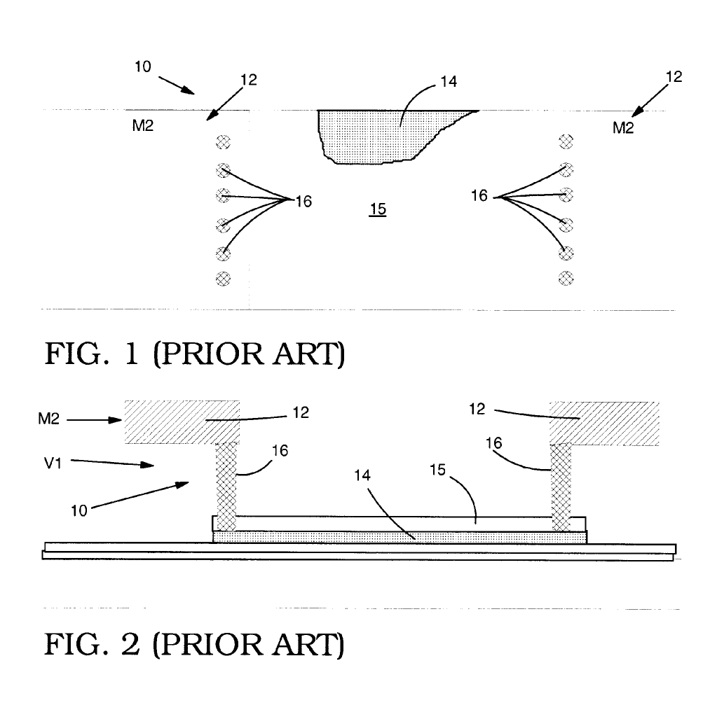

Referring to FIGS. 1 and 2, current density in a conventional BEOL thin film resistor 14 is determined mainly by the interconnecting contact vias 16, not by the resistor material. As a result, electromigration of the connecting contact vias 16 limit the maximum current density of BEOL thin film resistor 14. In particular, the resistive heating and associated temperature rise in the connecting metal of metal layer 12 and contact vias 16, results in electromigration of, for example, copper (Cu), that prohibits achieving higher current densities for resistor 14.

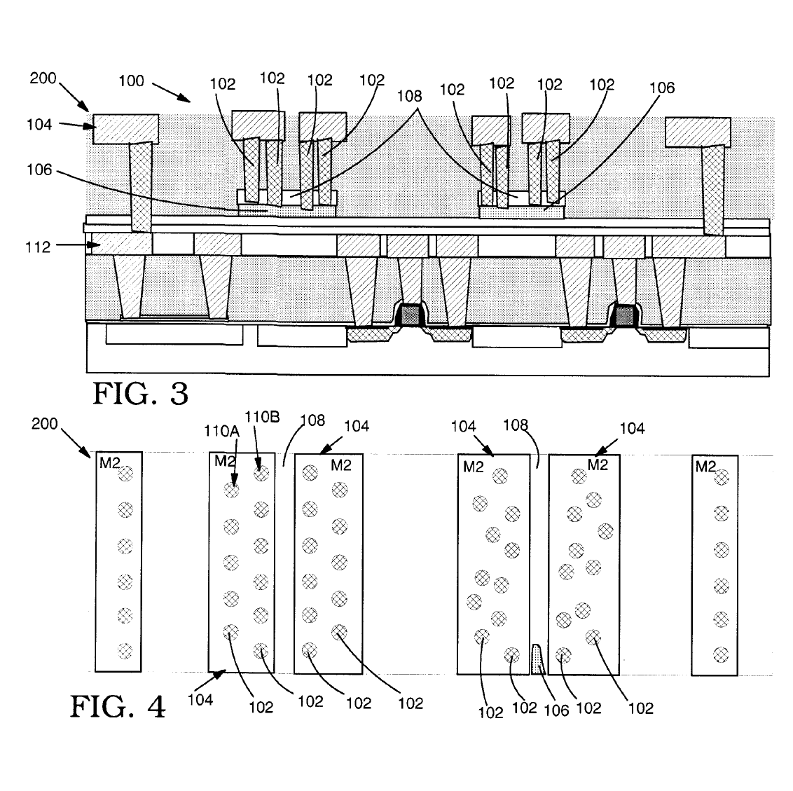

Referring to FIGS. 3 and 4, one embodiment of a contact via scheme 100 according to the invention is shown. Contact via scheme 100 includes a plurality of contact vias 102 connecting a metal layer 104 to a resistor 106. Metal layer 104 is a back end of line (BEOL) metal layer, i.e., a metal layer after first metal layer 112. Resistor 106 includes a BEOL thin film resistor, and may include a barrier layer 108, e.g., of silicon nitride (Si₃N₄), thereover. Resistor 106 is shown partially revealed in FIG. 4. Resistor 106 may include any now known thin film resistor material such as at least one of the following: tantalum nitride (TaN), tantalum (Ta), tungsten (W), titanium nitride (TiN) and titanium (Ti), or may include any later developed thin film resistor material. Each contact via 102 may include any now known contact via material such as at least one of the following: copper (Cu), aluminum (Al), and tungsten (W), or may include any later developed contact via material.

As shown in best in FIG. 4, the plurality of contact vias 102 are positioned in a staggered arrangement. There are a number of ways to arrange contact vias 102 in a staggered arrangement. In one embodiment, shown on the left side of FIG. 4, the plurality of contact vias 102 are arranged in a set of rows 11OA, 11OB with each row 11OA staggered or offset from an adjacent row 11OB. Although two rows 11OA, 11 OB for each metal wire of metal layer 104 is shown, it is understood that the number of rows may be greater than two. In an alternative embodiment, shown on the right side of FIG. 4, the plurality of contact vias 102 are staggered, but are not in rows. Any contact via scheme having a staggered arrangement is considered within the scope of the invention.

The above-described embodiments increase a current density of resistor 106 by mitigating electromigration and reducing the resistive heating of each contact via 102. In particular, each contact via 102 has a lower operating temperature than a non-staggered contact via 16 (FIGS.1-2) in a non-staggered arrangement. Contact via scheme 100 increases the current density of resistor 106 by increasing the number of current carrying contact vias 102 and by arranging contact vias 102 in the staggered arrangement, which redistributes the current at the ends of resistor 106. Hence, contact via scheme 100 decreases the current density per contact via 102 and enables a higher maximum current density for resistor 106. For example, resistor 106 may now achieve a current density greater than approximately 0.5 mA/μm width of resistor.

Turning to FIGS. 3,5 and 6, one embodiment of a method of connecting a metal layer 104 and a resistor 106 on a semiconductor chip, i.e., forming contact via scheme 100 (FIG. 3), according to the invention will now be described. Overall, the method includes forming a plurality of contact vias 102 connecting metal layer 104 to resistor 106, wherein the plurality of contact vias 102 are positioned in a staggered arrangement. It is understood that the embodiment shown is merely illustrative and that a large variety of other methods of forming contact via scheme 100 may be employed within the scope of the invention.

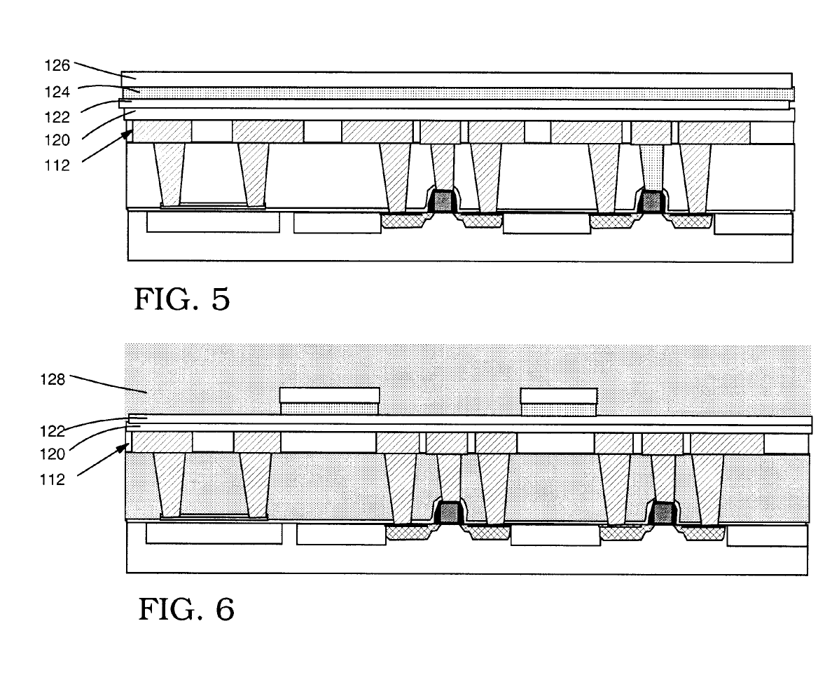

FIG. 5 shows a first step in which a barrier layer 120 of, for example, silicon nitride (Si₃N₄), nBlok (nitrogen doped silicon carbide (SiC)) or like material, is formed over first metal layer 112, followed by a dielectric layer 122 of, for example, hydrogenated silicon oxycarbide (SiCOH), followed by a resistor layer 124 of the above-described resistor material(s), followed by a barrier layer 126 of the above-described barrier layer material. Turning to FIG. 6, resistor layer 124 and barrier layer 126 are patterned. In one example, this step may include depositing and patterning a resist (not shown), followed by a resistor layer 124 and barrier layer 126 etch, optionally a diluted hydrofluoric acid (DHF) clean to remove any etch stop layer (not shown) used for resistor layer 124, and then a resist strip. Next, a dielectric layer 128 is deposited of, for example, SiCOH or tetraethyl orthosilicate (TEOS) (Si(OC₂H₅)₄), which is then polished.

Returning to FIG. 3, a next step may include forming a plurality of contact vias 102 by performing a dual damascene opening for metal layer 104 and contact via scheme 100, followed by deposition of a conductor, e.g., copper (Cu), aluminum (Al) or tungsten (W), to form metal layer 104 and contact vias 102. The dual damascene opening will create the staggered arrangement of contact vias 102. As described above, this step may include forming the plurality of contact vias 102 in a set of rows 11OA, 11OB (FIG. 4), each row offset from an adjacent row. Liners for metal layer 104 and contact vias 102 may also be provided, but they have been omitted for clarity in the drawings.

Another embodiment of the invention includes a semiconductor device 200 (FIGS. 3-4) including: a metal layer 104, a resistor 106, a first row 11OA of contact vias 102 connecting metal layer 104 to resistor 106, and at least one second row 11OB of contact vias 102 connecting metal layer 104 to resistor 106, wherein each row 11OA, 11OB of contact vias 102 is offset relative to an adjacent row of contact vias 102.

The foregoing description of various aspects of the invention has been presented for purposes of illustration and description. It is not intended to be exhaustive or to limit the invention to the precise form disclosed, and obviously, many modifications and variations are possible. Such modifications and variations that may be apparent to a person skilled in the art are intended to be included within the scope of the invention as defined by the accompanying claims.

What is claimed is:

1. A contact via scheme comprising:
a plurality of contact vias connecting a metal layer to a resistor, wherein the plurality of contact vias are positioned in a staggered arrangement.

2. The contact via scheme of claim 1, wherein the plurality of contact vias are arranged in a set of rows, each row offset from an adjacent row.

3. The contact via scheme of claim 1, wherein a current density of the resistor is greater than approximately 0.5 mA/μm width of the resistor.

4. The contact via scheme of claim 1, wherein the metal layer is a back end of line metal layer.

5. The contact via scheme of claim 1, wherein the resistor is a back end of line thin film resistor.

6. The contact via scheme of claim 1, wherein the resistor includes at least one of the following: tantalum nitride (TaN), tantalum (Ta), tungsten (W), titanium nitride (TiN) and titanium (Ti).

7. The contact via scheme of claim 1, wherein each contact via includes at least one of the following: copper (Cu), aluminum (Al) and tungsten (W).

8. A method of connecting a metal layer and a resistor on a semiconductor chip, the method comprising the step of:
forming a plurality of contact vias connecting the metal layer to the resistor, wherein the plurality of contact vias are positioned in a staggered arrangement.

9. The method of claim 8, wherein the forming step includes forming the plurality of contact vias in a set of rows, each row offset from an adjacent row.

10. The method of claim 8, wherein a current density of the resistor is greater than approximately 0.5 mA/μm width of the resistor.

11. The method of claim 8, wherein the metal layer is a back end of line metal layer and the resistor is a back end of line thin film resistor.

12. The method of claim 8, wherein the resistor includes at least one of the following: tantalum nitride (TaN), tantalum (Ta), tungsten (W), titanium nitride (TiN) and titanium (Ti).

13. The method of claim 8, wherein each contact via includes at least one of the following: copper (Cu), aluminum (Al) and tungsten (W).

14. A semiconductor device comprising:
a metal layer;
a resistor;
a first row of contact vias connecting the metal layer to the resistor; and
at least one second row of contact vias connecting the metal layer to the resistor,
wherein each row of contact vias is offset relative to an adjacent row of contact vias.

15. The semiconductor device of claim 14, further comprising a dielectric layer below the resistor.

16. The semiconductor device of claim 14, wherein a current density of the resistor is greater than approximately 0.5 mA/μm width of the resistor.

17. The semiconductor device of claim 14, wherein the metal layer is a back end of line metal layer.

18. The semiconductor device of claim 14, wherein the resistor is a back end of line thin film resistor.

19. The semiconductor device of claim 14, wherein the resistor includes at least one of the following: tantalum nitride (TaN), tantalum (Ta), tungsten (W), titanium nitride (TiN) and titanium (Ti).

20. The semiconductor device of claim 14, wherein each contact via includes at least one of the following: copper (Cu), aluminum (Al) and tungsten (W).
